(19) United States
(12) Patent Application Publication
(10) Pub. No.: US 2005/0118531 A1
(43) Pub. Date: Jun. 2, 2005

(54) METHOD FOR CONTROLLING CRITICAL DIMENSION BY UTILIZING RESIST SIDEWALL PROTECTION

(76) Inventors: Hsiu-Chun Lee, Taipei City (TW); Tse-Yao Huang, Taipei City (TW); Yi-Nan Chen, Taipei City (TW)

Correspondence Address: NORTH AMERICA INTERNATIONAL PATENT OFFICE (NAIPC), P.O. BOX 506, MERRIFIELD, VA, 22116, US

(21) Appl. No.: 10/707,259

(22) Filed: Dec. 2, 2003

(51) Int. Cl. G03F 7/00; G03F 7/36

(52) U.S. Cl. 430/311; 430/313; 430/314

(57) ABSTRACT

A method for controlling line width critical dimension is disclosed. A semiconductor layer is deposited on a substrate. A cap layer is formed on the semiconductor layer. A patterned photoresist is formed on the cap layer. The patterned photoresist has a top surface and vertical sidewalls. A silicon thin film is selectively sputtered on the top surface and vertical sidewalls of the patterned photoresist, but not on the cap layer. The silicon thin film, which has a thickness: x above the top surface and a thickness: y on the sidewalls of the patterned photoresist, wherein xx<, is used to protect the patterned photoresist. Using the silicon thin film and the patterned photoresist as an etching mask, the cap layer is anisotropically etched thereby transferring the photoresists pattern to the cap layer. Finally, using the cap layer as an etching mask, the semiconductor layer is etched.

### BACKGROUND OF INVENTION

1. Field of the Invention

The present invention relates to semiconductor fabrication processes. More particularly, the present invention relates to a critical dimension (CD) control method for semiconductor fabrication processes. According to the present invention method, one skill in the art is capable of making a nano-scale gate structure with an After-Etch-Inspection CD (AEI CD) that is substantially equal to After-Develop-Inspection CD (ADI CD) thereof.

2. Description of the Prior Art

n the fabrication of semiconductor devices, it is typical to use photoresist layer on a semiconductor wafer to mask a predetermined pattern for subsequent etching or ion implantation processes. The patterned photoresist is usually formed by, firstly, coating the photoresist, exposing it to suitable radiation (UV, EUV, e-beam, etc.), and then developing (and baking) the exposed photoresist. For positive-type photoresist, for example, the irradiated parts of the photoresist are chemically removed in the development step to expose areas of the underlying layer where are to be etched. As known in the art, quality inspections are carried out after development and after etching, respectively, to ensure good quality of the device critical dimensions (CDs), which are also referred to as After-Develop-Inspection CD (ADI CD) and After-Etch-Inspection CD (AEI CD). These quality control procedures are designed to remedy any process anomaly in time.

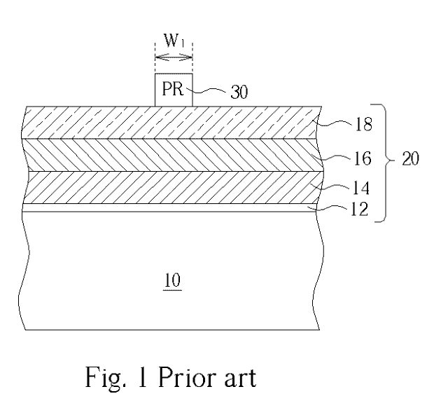

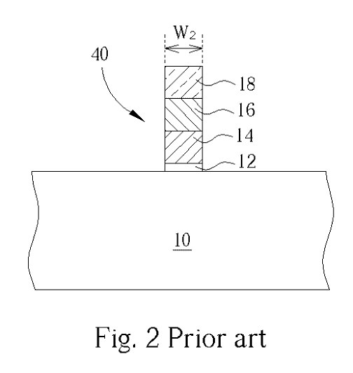

As the feature size of the semiconductor devices shrinks, the difference between the ADI CD and AEI CD becomes larger. This turns out to be a serious problem when the device dimension shrinks to nano scale and beyond. Referring to FIG. 1 and FIG. 2, the prior art processes for defining a sub-micro or nano-scale gate structure as an example are schematically demonstrated. On a main surface of a semiconductor substrate 10, a gate dielectric layer 12, a polysilicon layer 14, a tungsten silicide layer 16, and a silicon nitride cap layer 18 are sequentially deposited to constitute a stacked structure 20. A photoresist layer (not explicitly shown) is coated on the top of the stacked structure 20. The photoresist layer is subjected to conventional lithography to transfer a gate pattern on a photo mask to the photoresist layer. In FIG. 1, the gate pattern transferred to the photoresist is denoted with numeral 30 and has an ADI CD of W₁. Using the photoresist (PR) gate pattern 30 as an etching mask, according to the prior art, an anisotropic dry etching is performed to etch away the non-masked silicon nitride cap layer 18, thereby transferring the gate pattern 30 to the silicon nitride cap layer 18. Thereafter, using the patterned silicon nitride cap layer 18 as an etching hard mask, the dry etching continues to etch the exposed tungsten silicide layer 16 and the polysilicon layer 14, thereby forming a gate structure 40, as shown in FIG. 2. The resultant gate structure 40 has an AEI CD of W₂. In most cases, it is desired to have an ADI CD (W₁) that is substantially equal to the AEI CD (W₂), because it directly affects the channel length of a transistor device. However, in practice, the AEI CD (W₂) is significantly smaller than ADI CD (W₁).

One approach to solving the above-mentioned problem is increasing the ADI CD of the gate pattern 30 for compensating the CD loss during the subsequent dry etching. Unfortunately, this prior art method is difficult to control and is not cost-effective. Consequently, there is a constant need in this industry to provide a method for improving nano-scale gate fabrication such that the ADI CD (W₁) is substantially equal to the AEI CD (W₂).

### SUMMARY OF INVENTION

It is therefore the primary object of the present invention to provide a method for controlling critical dimensions in the fabrication of semiconductor features. According to the present invention, a reliable and effective method is provided for making a nano-scale gate structure with an After-Etch-Inspection CD (AEI CD) that is substantially equal to After-Develop-Inspection CD (ADI CD) thereof.

In accordance with the claimed invention, a critical dimension (CD) control method for semiconductor fabrication processes is provided. A silicon or semiconductor substrate is provided. A semiconductor layer such as a polysilicon layer is deposited on the substrate. A cap layer is then deposited on the semiconductor layer. A photoresist pattern is formed on the cap layer by lithography. The photoresist pattern has a top surface and vertical sidewalls. A silicon thin film is selectively sputterred on the top surface and vertical sidewalls of the photoresist pattern, but substantially not on the cap layer. Using the silicon thin film and the photoresist pattern as etching hard mask, an anisotropic dry etching is carried out to etch the cap layer, thereby transferring the photoresist pattern to the cap layer. The anisotropic dry etching continues, using said patterned cap layer as etching hard mask to etch the semiconductor layer. According to the claimed invention, thickness of the silicon thin film on the vertical sidewalls is “x”, while thickness of the silicon thin film on the top surface is “y”, wherein xx<, preferably, xx<0 angstroms.

Other objects, advantages and novel features of the invention will become more clearly and readily apparent from the following detailed description when taken in conjunction with the accompanying drawings.

### BRIEF DESCRIPTION OF DRAWINGS

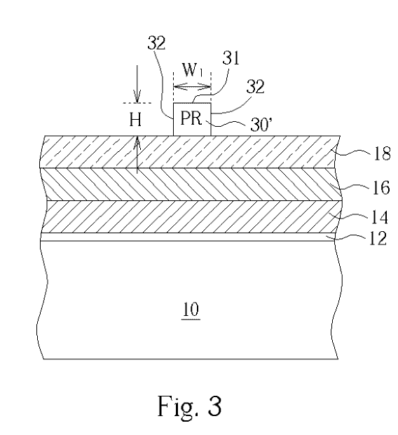

The accompanying drawings are included to provide a further understanding of the invention, and are incorporated in and constitute a part of this specification. The drawings illustrate embodiments of the invention and, together with the description, serve to explain the principles of the invention. In the drawings: FIG. 1 and FIG. 2 demonstrate the prior art processes for defining a sub-micro or nano-scale gate structure in cross-sectional views; and—FIG. 3 to FIG. 6 are schematic cross-sectional diagrams showing the method for controlling critical dimensions by utilizing photoresist sidewall protection according to one preferred embodiment of the present invention.

### DETAILED DESCRIPTION

Please refer to FIG. 3 to FIG. 6. FIG. 3 to FIG. 6 are schematic cross-sectional diagrams showing the method for controlling critical dimensions in the fabrication of a nanoscale gate structure according to one preferred embodiment of the present invention. It is to be understood that the embodiment illustrated through FIG. 3 to FIG. 6 is only exemplary. Those skilled in the art should know that the present invention could be applied in making other semiconductor features in the fabrication of integrated circuits, for example, definition of contact holes, for improving variation between ADI CD and AEI CD. As shown in FIG. 3, a semiconductor substrate 10 is provided. A gate dielectric layer 12, a polysilicon layer 14, a tungsten silicide layer 16, and a silicon nitride cap layer 18 are sequentially deposited on a main surface of the semiconductor substrate 10 to form a stacked structure 20. A photoresist layer (not explicitly shown) is coated on the top of the stacked structure 20. The photoresist layer is subjected to conventional lithography to transfer a gate pattern on a photo mask to the photoresist layer. In FIG. 3, the gate pattern transferred to the photoresist is denoted with numeral 30 and has an ADI CD of W₁ and a thickness of H, wherein the thickness of H is smaller than typical thickness as used in the prior art methods. The photoresist gate pattern 30 has a top surface 31 and vertical sidewalls 32. According to the preferred embodiment, the photoresist layer is commercially available positive-type photoresist. In another case, a bottom anti-reflection coating (BARC) may be interposed between the photoresist layer and the silicon nitride cap layer 18.

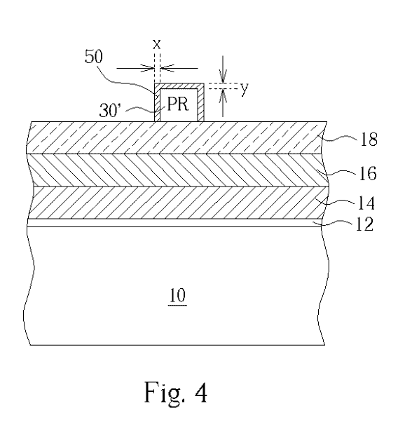

As shown in FIG. 4, subsequently, a sputtered silicon thin film 50 is selectively coated on the top surface 31 and the vertical sidewalls 32 of the photoresist gate pattern 30. The exposed surface of the silicon nitride cap layer 18 that is not masked by the photoresist gate pattern 30 is substantially not sputtered with any silicon thin film. A selective silicon sputtering method is used to complete such selective silicon coating on the photoresist surface. The silicon thin film 50 has a thickness at the sidewalls 32 that is smaller than that at the top surface 31. As denoted, the thickness of the silicon thin film 50 on the sidewalls 32 is “x”, while the thickness of the silicon thin film 50 on the top surface 31 is “y”, wherein xx<. Preferably, x is less than 50 angstroms, more preferably, x is less than 10 angstroms.

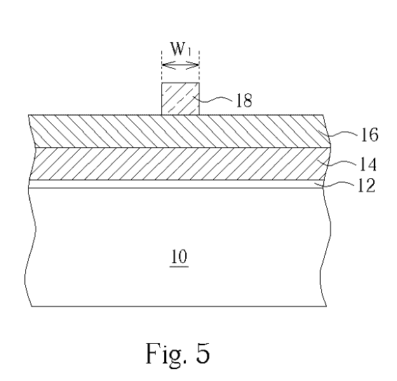

As shown in FIG. 5, using the sputtered silicon thin film 50 and the photoresist gate pattern 30 as etching hard mask, an anisotropic plasma dry etching is carried out to etch the silicon nitride cap layer 18. Since the sputtered silicon thin film 50 compensates the lateral etching in this etching step, there is substantially no CD loss when transferring the photoresist gate pattern 30 to the silicon nitride cap layer 18. The present invention features the use of sputtered silicon thin film 50 to protect the sidewalls 32 of the fine line photoresist gate pattern 30 when transferring the photoresist gate pattern 30 to the silicon nitride cap layer 18. The AEI CD of the gate pattern formed in the silicon nitride cap layer 18 transferred from the photoresist gate pattern 30 is W₁ that is substantially equal to the ADI CD of the photoresist gate pattern 30. Moreover, it is advantageous to use the present invention because the accuracy of pattern transferring may be improved. The unexpected accuracy improvement results from that the photoresist gate pattern 30 is protected by the sputtered silicon thin film 50, and can be thus thinner, bringing out some benefits during lithographic process.

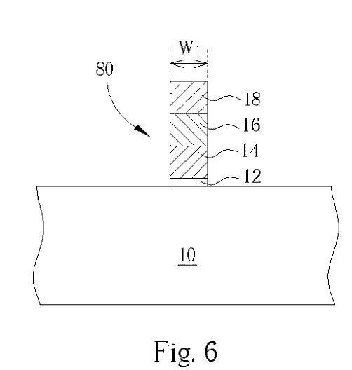

As shown in FIG. 6, gate pattern is transferred to the silicon nitride cap layer 18. The sputtered silicon thin film 50 and the photoresist gate pattern 30 are consumed. The dry etching continues, using the patterned silicon nitride cap layer 18 as a hard mask, the tungsten silicide layer 16 and the polysilicon layer 14 are etched to form a gate structure 80 having an AEI CD of W₁ that is substantially equal to the ADI CD of the photoresist gate pattern 30.

Those skilled in the art will readily observe that numerous modification and alterations of the device may be made while retaining the teachings of the invention. Accordingly, the above disclosure should be construed as limited only by the metes and bounds of the appended claims.

1. A critical dimension (CD) control method for semiconductor fabrication processes, comprising:
providing a substrate;
depositing a semiconductor layer on said substrate;
depositing a cap layer on said semiconductor layer;
forming a photoresist pattern on said cap layer, the photoresist pattern having a top surface and vertical sidewalls;
selectively sputtering a silicon thin film on said top surface and said vertical sidewalls of said photoresist pattern, but substantially not on said cap layer;
using said silicon thin film and said photoresist pattern as etching hard mask, carrying out an anisotropic dry etching to etch said cap layer, thereby transferring said photoresist pattern to said cap layer; and
continuing said anisotropic dry etching, using said patterned cap layer as etching hard mask to etch said semiconductor layer.

2. The CD control method for semiconductor fabrication processes according to claim 1 wherein said semiconductor layer comprises a polysilicon layer.

3. The CD control method for semiconductor fabrication processes according to claim 1 wherein said semiconductor layer comprises a silicide layer.

4. The CD control method for semiconductor fabrication processes according to claim 1 wherein said cap layer is made of silicon nitride.

5. The CD control method for semiconductor fabrication processes according to claim 1 wherein thickness of said silicon thin film on said vertical sidewalls is “x”, while thickness of said silicon thin film on said top surface is “y”, wherein xx<.

6. The CD control method for semiconductor fabrication processes according to claim 5 wherein xx<0 angstroms.

7. The CD control method for semiconductor fabrication processes according to claim 5 wherein xx<0 angstroms.
